(19) United States
(12) Patent Application Publication
(10) Pub. No.: US 2004/0036103 A1
(43) Pub. Date: Feb. 26, 2004

(54) Memory device and method of manufacturing the same

(75) Inventors: Hsu-Shun Chen, Yunlin (TW); Li-Hsin Chuang, Hsinchu (TW); Hsiang-Lan Long, Hsinchu (TW); Yi-Chou Chen, Hsinchu (TW)

Correspondence Address: Finnegan, Henderson, Farabow,, Garrett & Dunner, L.L.P., 1300 I Street, N.W., Washington, DC, 20005-3315, US

(73) Assignee: Macronix International Co., Ltd.

(21) Appl. No.: 10/223,327

(22) Filed: Aug. 20, 2002

(51) Int. Cl. H01L 21/8242

(52) U.S. Cl. 257/303; 257/300; 438/253; 438/396

(57) ABSTRACT

A method of fabricating a memory device that includes defining a semiconductor substrate of a first dopant type, providing a doped layer of a second dopant type over the substrate, providing a dielectric layer over the doped layer, forming a plug in the dielectric layer, doping the plug with a dopant of the second type substantially over the entire region of the plug, doping the plug having doped with the second dopant type with a dopant of the first type, and providing a memory cell over the plug.

### DESCRIPTION OF THE INVENTION

1. Field of the Invention

This invention pertains in general to a semiconductor circuit device and method of fabricating the device. More particularly, this invention relates to semiconductor memory cells and methods of fabricating the cells.

2. Background of the Invention

Memory cells using electrically writable and erasable phase change materials are well known in the art, and are disclosed, for example, in U.S. Pat. Nos. 4,599,705, 5,837,564, 5,920,788, 5,998,244 and 6,236,059, the disclosures of which are incorporated herein by reference. In conventional memory cell structures, a diode with buried bit lines in the X or Y axis is used to address and isolate individual cells. The buried bit lines are formed in source or drain regions of the memory cells. However, a large depletion region sometimes exists in the buried bit line regions that may give rise to a punchthrough phenomenon.

Punchthrough is a breakdown phenomenon caused by the widening of a drain depletion region when a reverse-biased voltage on the drain is increased. The electric field in the reverse-biased drain may penetrate the source region and reduce the energy barrier of the source-to-drain junction. Therefore, the shorter the channel length of an MOS device, the more likely the punchthrough phenomenon will occur. Unintended device punchthrough is a severe problem in sub-micron devices as the device critical dimension continues to decrease in the advanced semiconductor manufacturing processes.

### SUMMARY OF THE INVENTION

Accordingly, the present invention is directed to memory cells and method of fabricating the cells that obviate one or more of the problems due to limitations and disadvantages of the related art.

Additional features and advantages of the invention will be set forth in the description which follows, and in part will be apparent from the description, or may be learned by practice of the invention. The objectives and other advantages of the invention will be realized and attained by the circuit structures particularly pointed out in the written description and claims thereof, as well as the appended drawing.

To achieve these and other advantages, and in accordance with the purpose of the invention as embodied and broadly described, there is provided a method of fabricating a memory device that includes defining a semiconductor substrate of a first dopant type, providing a doped layer of a second dopant type over the substrate, providing a dielectric layer over the doped layer, forming a plug in the dielectric layer, doping the plug with a dopant of the second type substantially over the entire region of the plug, doping the plug having doped with the second dopant type with a dopant of the first type, and providing a memory cell over the plug.

Also in accordance with the present invention, there is provided a method of fabricating a memory device that includes defining a semiconductor substrate, providing a doped layer type over the substrate, providing a dielectric layer over the doped layer, forming a plurality of trenches in the dielectric layer, at least one of the trenches exposes the doped layer, depositing polysilicon in the trenches to form a plurality of plugs, providing a substantially uniform distribution of a first dopant type in the plugs, doping the plugs having doped with the first dopant type with a second dopant type, wherein the second dopant type is doped only in upper portions of the plugs, and forming a plurality of memory cells over the plugs.

Further in accordance with the present invention, there is provided memory device that includes a semiconductor substrate of a first dopant type, a doped layer of a second dopant type formed over the substrate, a dielectric layer formed over the doped layer, a plug formed in the dielectric layer having a first doped region of the second dopant type and a second doped region of the first dopant type over the first doped region, and a memory cell formed over the plug.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the objects, advantages, and principles of the invention.

In the drawings,

FIGS. 1A to 1C show the steps of fabricating a memory cell consistent with one embodiment of the present invention; and

FIG. 2 shows a cross-sectional view of a memory device consistent with one embodiment of the present invention.

### DESCRIPTION OF THE EMBODIMENTS

Reference will now be made in detail to the present embodiments of the invention, examples of which are illustrated in the accompanying drawings. Wherever possible, the same reference numbers will be used throughout the drawings to refer to the same or like parts.

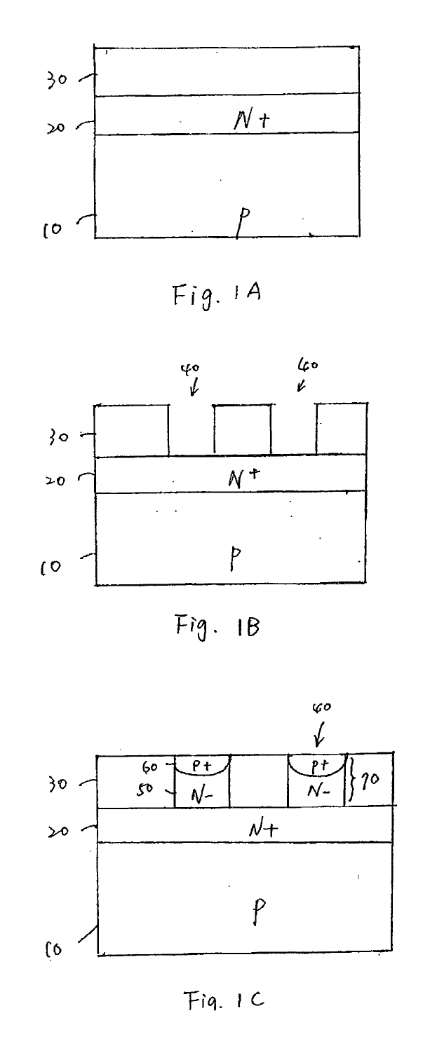

FIGS. 1A to 1C show the manufacturing steps of a memory cell in accordance with the method of the present invention. Referring to FIG. 1A, the method of the invention begins with defining a semiconductor substrate 10, for example, a p-type substrate. A doped layer 20 is then provided over the substrate 10. The doped layer 20 serves as a buried bit line for a memory cell. In one embodiment, the doped layer 20 is heavily doped with n-type dopants, such as phosphorus, antimony, or arsenic at energies and dosages ranging from approximately 35 to 150 keV and 5×10¹⁹ to 5×10²⁰ atoms per cm², respectively. The dopants may be introduced through ion implantation. After the formation of the doped layer 20, a dielectric layer 30 having a thickness of approximately 200 to 600 nm is deposited over the doped layer 20. The dielectric layer 30 may be an oxide layer.

Referring to FIG. 1B, a plurality of trenches, or vias, exposing the underlying doped layer 20 are formed in the dielectric layer 30 by conventional masking and etching processes. Although a two-diode or memory cell array is described in the embodiment, the discussion is applicable to diode arrays of virtually any size.

Referring to FIG. 1C, following the formation of the trenches 40, polysilicon is deposited into the trenches 40 to form a plurality of plugs 70. The polysilicon may be deposited with in-situ chemical-vapor deposition process. The plugs 70 are lightly doped with n-type dopants such as phosphorus, antimony, or arsenic to form a first doped regions 50 in the plugs 70. The n-type dopants in the first doped region 50 may be introduced at an energy ranging from approximately 35 to 150 keV and a dosage ranging from approximately 3×10¹³ to 1×10¹⁴ atoms per cm². In situ doped polysilicon generally contributes to a uniform distribution of dopants in the plugs 70.

The plugs 70 are then heavily doped with p-type dopants such as boron, gallium, or BF2 to form second doped regions 60 in the plugs 70. The p-type dopants in the second doped regions 60 may be introduced through blanket deposition at an energy ranging from approximately 50 to 150 keV and a dosage ranging from approximately 5×10¹⁹ to 5×10²⁰ atoms per cm². Conventional manufacturing process steps follow to complete the memory device.

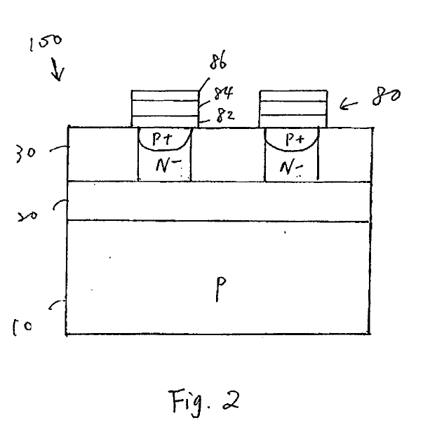

FIG. 2 shows a cross-sectional view of a memory device 100 consistent with one embodiment of the present invention. Referring to FIG. 2, the memory device 100 includes a plurality of programmable cells 80. Each of the programmable cell 80 includes a lower electrode 82, a phase change layer 84, and an upper electrode 86. The phase change layer 84 may comprise chalcogenide. The materials for the upper and lower electrodes 86 and 82 may be selected from a group of carbon, molybdenum, and titanium nitride, and the chalcogenide material may be selected from a group of Te, Se, Sb, and Ge.

Provided directly beneath each of the programmable cells 80 is a plug 70 formed in an dielectric layer having a first doped region and a second doped region. The plug 70 is contiguous with the programmable cell 80 and the buried bit line 20. In operation, each of the plugs 70 functions to prevent punchthrough and therefore minimizing any disburse issues in the memory device 100.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of fabricating a memory device, comprising:
defining a semiconductor substrate of a first dopant type;
providing a doped layer of a second dopant type over the substrate;
providing a dielectric layer over the doped layer;
forming a plug in the dielectric layer;
doping the plug with a dopant of the second type substantially over the entire region of the plug;
doping the plug having doped with the second dopant type with a dopant of the first type; and
providing a memory cell over the plug.

2. The method of claim 1, wherein the doped layer is a buried bit line.

3. The method of claim 1, wherein forming a plug includes forming a trench in the dielectric layer to expose the doped layer; and
depositing polysilicon in the trench.

4. The method of claim 1, wherein the plug is doped with a dopant of the second type at an energy ranging from approximately 35 to 150 keV and a dosage ranging from approximately 3×10¹³ to 1×10¹⁴ atoms per cm².

5. The method of claim 1, wherein the plug is doped with a dopant of the first type at an energy ranging from approximately 50 to 150 keV and a dosage ranging from approximately 5×10¹⁹ to 5×10²⁰ atoms per cm².

6. A method of fabricating a memory device, comprising:
defining a semiconductor substrate;
providing a doped layer type over the substrate;
providing a dielectric layer over the doped layer;
forming a plurality of trenches in the dielectric layer, at least one of the trenches exposes the doped layer;
depositing polysilicon in the trenches to form a plurality of plugs;
providing a substantially uniform distribution of a first dopant type in the plugs;
doping the plugs having doped with the first dopant type with a second dopant type, wherein the second dopant type is doped only in upper portions of the plugs; and
forming a plurality of memory cells over the plugs.

7. The method of claim 6, wherein the doped layer is a buried bit line.

8. A memory device, comprising:
a semiconductor substrate of a first dopant type;
a doped layer of a second dopant type formed over the substrate;
a dielectric layer formed over the doped layer;
a plug formed in the dielectric layer having a first doped region of the second dopant type and a second doped region of the first dopant type over the first doped region; and
a memory cell formed over the plug.

9. The memory device of claim 8, wherein the first dopant type is p-type, and the second dopant type is n-type.

10. The memory device of claim 8, wherein the plug is contiguous with the doped layer.

11. The memory device of claim 10, wherein the doped layer is a buried bit line.

12. The memory device of claim 10, wherein the first doped region of the plug is contiguous with the memory cell.

13. The memory device of claim 8, wherein the memory cell is contiguous with the plug.

14. The memory device of claim 13, wherein the second doped region of the plug is contiguous with the memory cell.
